(19) United States
(12) Patent Application Publication
(10) Pub. No.: US 2024/0280892 A1
(43) Pub. Date: Aug. 22, 2024

(54) METHOD FOR CORRECTING ERRORS IN PHOTOLITHOGRAPHIC MASKS WHILE AVOIDING DAMAGE TO REAR-SIDE COATINGS

(71) Applicant: Carl Zeiss SMS Ltd., Misgav (IL)

(72) Inventors: Vladimir Dmitriev, Tzurit (IL); Avi Cohen, Haifa (IL); Kujan Gorhad, Northern Israel (IL); Hani Zeidan, Daliyat al-Karmel (IL)

(21) Appl. No.: 18/443,486

(22) Filed: Feb. 16, 2024

(30) Foreign Application Priority Data
Feb. 16, 2023 (DE) 102023103904.0

(51) Int. Cl. G03F 1/36; G03F 1/72; G03F 7/00

(52) U.S. Cl. CPC G03F 1/36; G03F 1/72; G03F 7/70508

(57) ABSTRACT

The present invention relates to a method for correcting placement errors in a photolithographic mask comprising a substrate and structures formed on the substrate, the method involving at least one local density change, preferably a plurality of local density changes, each of which defines a pixel, being introduced into the substrate by use of a laser beam in order to correct placement errors of the structures, wherein in an examination step, an incidence surface of the mask, via which the laser beam radiates into the substrate, is examined for contaminations and, in regions in which a contamination of the incidence surface has been ascertained in the examination step, no laser irradiation or a laser irradiation with at least one changed laser beam parameter takes place, the laser beam parameter(s) being changed such that no damage to the incidence surface or near-surface regions occurs in the case of an interaction between laser beam and contamination.

### CROSS-REFERENCE TO RELATED APPLICATION

This application claims priority under 35 U.S.C. § 119 from German Application No. 10 2023 103 904, filed on Feb. 16, 2023, the entire contents of which is incorporated herein by reference.

### TECHNICAL FIELD

The present invention relates to a method for correcting placement errors in a photolithographic mask which can be used for imaging structures in a projection exposure apparatus, the mask comprising a substrate and structures formed on the substrate, and the method involving at least one local density change, preferably a plurality of local density changes, each of which defines a pixel, being introduced into the substrate by use of a laser beam in order to correct placement errors of the structures.

### BACKGROUND

Microstructured or nanostructured components pertaining to electrical engineering or microsystems engineering are manufactured using microlithographic methods in which structures arranged on a mask or a reticle are imaged onto a photoresist in a reducing manner by use of projection exposure apparatuses in order to produce the structures on the components to be manufactured, such as wafers and the like, by use of corresponding microlithographic methods. Since ever smaller structures are to be produced, projection exposure apparatuses which operate with operating light in the wavelength spectrum of extreme ultraviolet light (EUV light) are now being used. Accordingly, the photolithographic masks have to satisfy stringent requirements in respect of the exactness of their geometric shape. However, photolithographic masks of this type may have placement errors of pattern or structure elements, with the result that some of the structures are not imaged into the photoresist precisely at the predetermined position.

In this respect, it is known that by introducing local density variations into a part of the substrate of the mask in the region of the placement errors, the corresponding structures can be displaced in order to compensate for the placement errors. This is described for example in the documents DE 10 2006 054 820 A1 or DE 10 2011 078 927 A1, the content of which is incorporated by reference in its entirety.

The local density variations in the mask substrate are attained by locally and temporarily heating or melting the substrate material by use of lasers, and in particular pulsed lasers, such as femtosecond lasers. The density of the substrate is reduced locally in the region in which the material has been temporarily melted or correspondingly heated, a volume region whose density is changed locally by a laser beam being referred to as a pixel.

The so-called writing of the pixels is usually effected by a laser from the rear side of the mask, which is situated opposite the side on which the structures of the mask are arranged and which, in the case of a reflective mask for EUV microlithography, has a corresponding reflection coating for the EUV radiation. However, an electrically conductive rear-side coating is usually provided on the rear side as well, and is intended not to be damaged by the laser irradiation.

The problem arises here that damage to the rear side of the mask may occur in some instances.

### SUMMARY

It is therefore an aspect of the present invention to provide a method for correcting placement errors in the case of photolithographic masks in which the problem of damage to rear-side coatings or near-surface regions of the rear side of the mask is avoided or reduced. Furthermore, the method for correcting placement errors of the structures of the mask is intended to be simply and efficiently applicable.

This aspect is achieved by a method having the features of Claim 1. The dependent claims relate to advantageous configurations of the invention.

The invention is based on the insight that rear-side damage to the mask may be caused by contaminations which are present on the rear side of the mask and may interact with an incident laser beam, with the result that instances of melting or the like may be caused. Therefore, for the purpose of correcting placement errors in a photolithographic mask comprising a substrate and structures formed on the substrate, it is proposed, before introducing local density changes into the substrate by use of a laser beam, in an examination step, to examine an incidence surface of the mask, via which the laser beam radiates into the substrate, for contaminations in order to be able to ascertain corresponding contaminations. If a contamination on the incidence surface is ascertained in the examination step, in this region no laser irradiation or a laser irradiation with at least one changed laser beam parameter is carried out, the laser beam parameter(s) being changed such that no damage to the incidence surface or near-surface regions occurs in the case of an interaction between laser beam and contamination, in order to avoid rear-side damage to the mask.

Appropriate laser beam parameters that can be changed in order to avoid rear-side damage include the location of the focal point in the substrate, the numerical aperture of the laser beam, the wavelength of the laser beam light used, the writing speed of the laser beam with regard to the number of pixels per unit time, the focal point size of the laser beam, the beam diameter at the incidence surface, the energy of the laser beam, the beam intensity of the laser beam, the intensity profile of the laser beam, the pulse duration, the repetition rate, the pulse power and the pulse power density in the case of pulsed lasers.

In particular, in the case of the laser irradiation in the region of contaminations on the incidence surface, it is possible to implement at least one of the measures comprising increasing the numerical aperture of the laser beam, reducing the laser beam intensity, reducing the repetition rate, reducing the writing speed with regard to the number of pixels per unit time, reducing the laser beam energy, reducing the pulse power, reducing the pulse duration and reducing the pulse power density.

Dispensing with the laser irradiation or a laser irradiation with at least one changed laser beam parameter can be provided only in a region with the contamination or in a region with the contamination and a defined margin around the contamination. Since the pixels are usually produced in the substrate below the incidence surface, the region of the contamination can be determined by use of a projection of the contamination into the plane(s) of the pixels. The same applies to a surrounding margin in which no laser irradiation or a laser irradiation with at least one changed laser beam parameter takes place, in which case the circumferential margin can be defined by a spacing from the contamination of the order of magnitude of 1 to 100 times the largest dimension of the contamination along the incidence surface.

In order to correct the placement errors with the aid of the production of pixels, the required distribution and/or properties of the pixels and/or the laser beam parameters can be determined, as known from the prior art, e.g. from the document DE 10 2011 078 927 A1. After the determination of the pixels and/or writing parameters required for the correction, according to the invention the laser incidence surface is examined for contaminations, and if contaminations are ascertained, corresponding regions are defined in which no local density changes are produced in the substrate, such that the pixels provided there are omitted. If no placement errors which are not tolerable remain as a result, the corresponding correction of the mask can be implemented with the remaining pixels. If the remaining placement errors cannot be tolerated, however, the determination of the distribution and/or the properties of the pixels and/or the laser beam parameters can be effected again taking account of the detected contaminations, such that a complete compensation of the pixel-free regions is effected with regard to the correction of the placement errors.

Alternatively, after the examination step for determining contaminations on the incidence surface in regions in which in the examination step a contamination of the incidence surface has been ascertained and, consequently, no laser irradiation takes place and no pixels with density variation are produced, a restricted compensation for omitted pixels can be implemented.

A restricted compensation for pixels which are omitted on account of contaminations can be effected by use of a fixedly predefined compensation which is effected independently of the properties of the contaminations or only depending on few or simple properties of the ascertained contaminations, in order to minimize the outlay. It goes without saying that the scope of the compensation and the outlay therefor can be chosen within wide ranges.

An approach for a heuristic compensation of omitted pixels can be provided depending on the ascertained contamination by the pixel(s) omitted in a region with the contamination and/or with a defined spacing around the contamination being displaced or offset to a location which lies on a circle or within a zone with a specific offset radius provided around the original pixel.

The distribution and/or properties of the pixels and/or the laser beam parameters can be optimized with regard to a minimization of the placement errors, in particular with regard to a minimization of the interval of ±3 σ (standard deviation) of the positioning. This applies generally to the correction of placement errors in masks with the aid of local density changes in the substrate of the mask, and in particular also to the compensation of pixels which are omitted on account of contaminations on the incidence surface of the mask and whose compensation is effected for example by use of a displacement or offset of the pixels. Accordingly, a heuristic compensation of omitted pixels can also comprise corresponding optimization steps.

### BRIEF DESCRIPTION OF THE DRAWINGS

In the accompanying drawings, purely schematically,

FIG. 1 schematically shows a block diagram of a device for the modification of a photolithographic mask,

FIG. 2 shows a partial cross-section through a reflective mask with a representation of the pixel production according to the present invention,

FIG. 3 shows a plan view of a part of the rear side of a mask with contaminations with additional representation of the pixels to be produced in the substrate and pixel-free regions in the region of the contaminations,

FIG. 4 shows a plan view of a part of the rear side of the mask from FIG. 3 with additional representation of offset pixels to be produced in the substrate,

FIG. 5 shows a representation of the pixel distribution (black: no pixels, white: high pixel concentration) over a surface of a mask in the case of heuristic compensation of omitted pixels in association with contaminations on the incidence surface by use of an offset of the omitted pixels with a spacing with different radii according to the partial images a), b) and c),

FIG. 6 shows, in the partial images a), b) and c), a representation of placement errors by indication of offset arrows over the surface after the heuristic compensation of omitted pixels according to FIG. 5,

FIG. 7 shows representations of the pixel distribution (black: no pixels, white: high pixel concentration) over a surface of a mask with contaminations, in the case of which no compensation of the pixels omitted on account of the contaminations (partial image a)), an optimized offset of omitted pixels (partial image b)) and a complete compensation of omitted pixels have been implemented,

FIG. 8 shows, in the partial images a), b) and c), a representation of placement errors by indication of offset arrows over the surface after the varying compensation of omitted pixels according to FIG. 7, and

FIG. 9 shows a diagram showing placement errors in the form of an interval of the 3-fold standard deviation as a function of the radius of the offset of an omitted pixel for various forms of the compensation of omitted pixels.

### DETAILED DESCRIPTION

Further advantages, characteristics and features of the present invention will become evident from the following detailed description of the exemplary embodiments. However, the invention is not restricted to these exemplary embodiments.

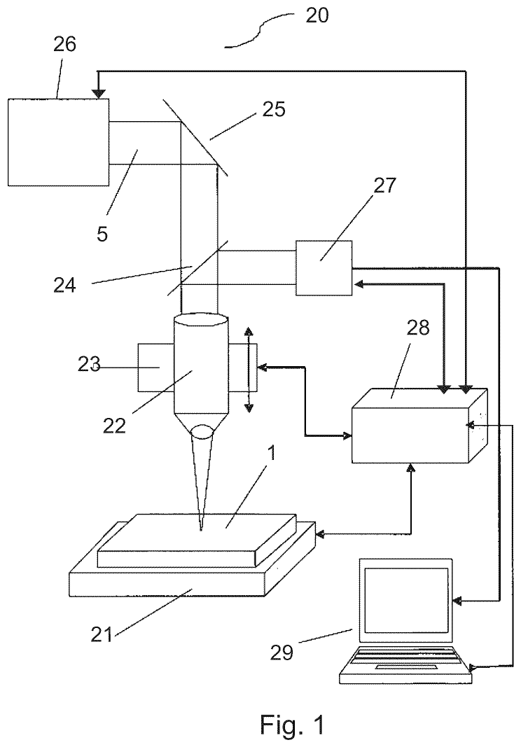

FIG. 1 shows a schematic block diagram of a device 20 for correcting placement errors according to the method of the present invention. The device 20 comprises a pulsed laser source 26 which generates a laser beam 5 or corresponding light pulses. The pulsed laser beam 5 is guided via the mirror 25 into a focusing lens 22, which can be adjusted via a positioning device 23 in accordance with the double arrow shown. The lens 22 focuses the pulsed laser beam 5 onto the photolithographic mask 1 in order to generate so-called pixels 6 in it. The mask 1 is held in a clamping device 21, which enables a two-dimensional displacement of the mask 1.

Furthermore, the device 20 comprises a detection system 27 for examination of contaminations, with which the mask 1 can be viewed via the dichromatic mirror 24 and contaminations on the surface of the mask 1 can be detected.

The device 20 also comprises a controller 28 to control the various components, such as pulse laser 26, positioning device 23 or the clamping device 21. In addition, a computer 29 is provided which can determine the contamination with the aid of the viewing system 27 and is set up to carry out the method described below in order to control the components of the device 20, such as the pulse laser 26, via the controller 28.

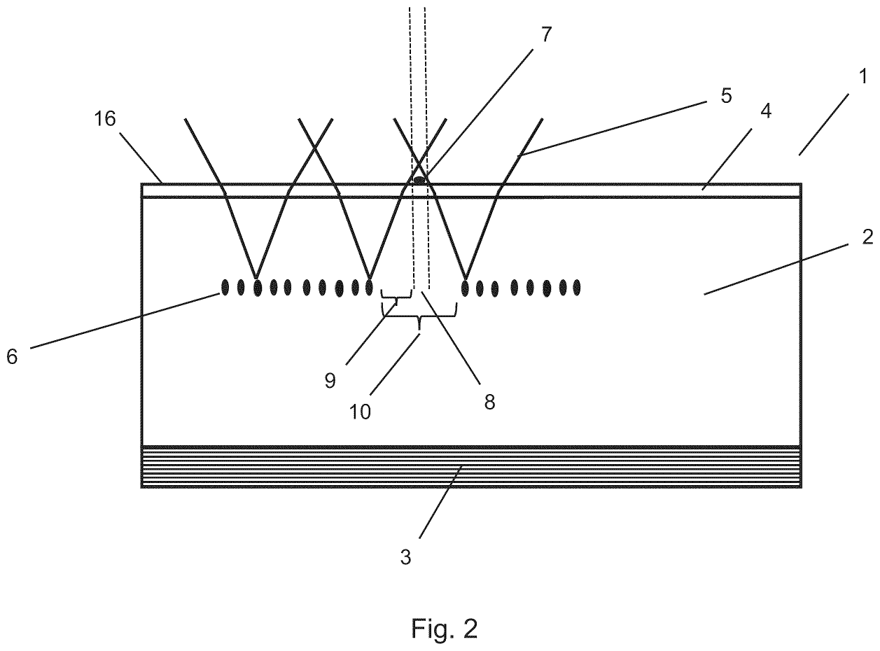

FIG. 2 shows a partial cross-section through a reflective mask such as is used for the microlithographic manufacture of micro- or nanostructured components pertaining to electrical engineering or microsystems engineering in projection exposure apparatuses which are operated with operating light in the wavelength range of extreme ultraviolet light (EUV light). The reflective mask 1 comprises a substrate 2 formed for example from quartz glass or glass-ceramic materials having a low coefficient of thermal expansion.

There is applied on the substrate 2 a reflection layer 3 composed of a plurality of alternating partial layers of molybdenum and silicon, for example, which form a so-called Bragg reflector in order to reflect the operating light of the projection exposure apparatus.

Corresponding structures (not shown) are also formed on the side of the mask with the reflection layer 3, which structures are intended to be imaged with the aid of the projection exposure apparatus and to be produced by microlithographic methods in the component to be manufactured. Opposite the reflection coating 3, which may additionally also comprise a capping layer, an electrically conductive rear-side coating 4 is provided on the rear side of the mask 1.

As is described in detail in DE 10 2011 078 927 A1 and U.S. Pat. No. 9,658,527, for example, in order to correct placement errors of the structures to be imaged, a plurality of local density variations, so-called pixels 6, can be produced in the substrate 2 in order to counteract corresponding placement errors of the structures of the mask 1 by use of the local density variations. The entire contents of DE 10 2011 078 927 A1 and U.S. Pat. No. 9,658,527 are incorporated by reference.

The example in FIG. 2 shows that in order to produce a pixel 6 or a local density variation, a laser beam 5 is focused onto a region within the substrate 2 of the mask 1 in order to produce a local density variation and to produce a so-called pixel 6 by use of local heating or melting of the substrate material.

As can likewise be gathered from FIG. 2, a plurality of such pixels 6 can be produced in the substrate 2 in order thereby to bring about a displacement of structures and hence correction of placement errors of the structures provided on the reflection side of the mask 1.

FIG. 2 also illustrates that on the incidence surface 16 or the rear side of the commercial mask 1, at which a laser beam 5 for producing a pixel 6 is radiated into the substrate 2, under certain circumstances contaminations 7, for example in the form of particles or the like, may be present, which may interact with the laser beam 5 during the production of the pixels 6, the so-called writing of the pixels 6, in which case the heating and melting of the contaminations and/or of the rear-side coating 4 may occur, which may lead to damage to the rear-side coating 4 and hence the mask 1.

Accordingly, as is illustrated in FIG. 2, according to the present invention, in the region in which a contamination is present on the incidence surface 16, no pixel 6 is produced in the underlying region of the substrate 2 in which a projection of the region of the contamination is present. Since the laser beam 5 is not focused until within the substrate 2, it has a certain extent on the incidence surface 16, such that in order to avoid an interaction between the laser beam 5 and the contamination 7, a larger region around the contamination 7, when the contamination 7 is projected into the plane in which the pixels 6 are produced, is not provided with pixels 6. This therefore concerns a region which is directly occupied by the contamination, and also a region around that when the region of the contamination 7 is projected into the plane of the pixels 6. In FIG. 2, the region 8 occupied by the contamination 7 on the incidence surface 16 is delimited by dashed lines, and in the plane of the pixels within the substrate 2 a circumferential margin 9 is provided, which surrounds the region 8 and together with the region 8 defines the pixel-free region 10 within the substrate 2. This procedure makes it possible to prevent the rear side of the mask 1 or the rear-side coating 4 or a near-surface region of the substrate 2 at the rear-side coating 4 from being damaged by an interaction between the laser beam 5 and a contamination 7. In some implementations, the circumferential margin 9 can be in a range from 1 to 100 times the largest dimension of the contamination 7.

As an alternative to completely dispensing with the introduction of corresponding pixels 6 into the region assigned to the respective contamination, the introduction of the pixels 6 can be varied such that no damage to the rear-side coating 4 or to a near-surface region thereof can occur. By way of example, a laser beam 5 having a changed wavelength can be used or the location of pixel production can be changed, for example shifted into a different plane in the substrate 2, such that the dimensions of the laser beam 5 and the focusing thereof can be changed. Other suitable parameters of the laser beam 5 or of the writing process for the pixels 6 can also be changed in order to avoid an unfavourable and harmful interaction between the laser beam 5 and a contamination 7.

In some implementations, when introducing the laser irradiation in the region of contaminations on the incidence surface, the introduction of the pixels 6 can be varied by changing at least one laser beam parameter. The at least one laser beam parameter can include, for example, at least one of the location of the focal point in the substrate, the numerical aperture of the laser beam, the wavelength of the laser beam light used, the writing speed of the laser beam with regard to the number of pixels per unit time, the focal point size of the laser beam, the beam diameter at the incidence surface, the energy of the laser beam, the beam intensity of the laser beam, or the intensity profile of the laser beam. When a pulsed laser is used, the at least one laser beam parameter can include, for example, at least one of the pulse duration, the repetition rate, the pulse power, or the pulse power density.

In some implementations, when introducing the laser irradiation in the region of contaminations on the incidence surface, the introduction of the pixels 6 can be varied by changing at least one laser beam parameter, for example, performing at least one of: increasing the numerical aperture of the laser beam, reducing the laser beam intensity, reducing the repetition rate of the laser pulses, reducing the writing speed with regard to the number of pixels per unit time, reducing the laser beam energy, reducing the laser pulse power, reducing the laser pulse duration, or reducing the laser pulse power density.

By omitting the pixels 6 in the corresponding region of the contamination 7, i.e. in the direct region 8 of the contamination and/or in a marginal region 9 around that, it is indeed possible to avoid damage to the rear-side coating 4 and to corresponding near-surface regions of the rear side of the mask 1, but at the same time, as a result, it is also not possible to bring about the originally envisaged correction of placement errors. Provided that the influence on the correction of the placement errors is within the permissible specification for the mask 1, no further measures are necessary.

However, if the remaining placement errors are not within the required specification, then it is possible to compensate for the omission of the pixels 6 in the region of the contamination 7.

A corresponding compensation can be effected by the fact that, taking account of the contaminations 7 ascertained on the rear side of the mask, the required pixels 6 for the correction of positioning errors of the structure elements are determined from scratch, i.e. a completely new calculation of the pixels 6 necessary for the correction of placement errors. One example for determining the pixels 6 necessary for a correction of placement errors is given in DE 10 2011 078 927 A1 and U.S. Pat. No. 9,658,527.

As is described in DE 10 2011 078 927 A1 and U.S. Pat. No. 9,658,527, in this case the number and position of the pixels and also the properties thereof and the way in which the pixels are produced can be optimized by the modification of the radiation parameters such that placement errors are optimally corrected. However, such a procedure is very time-consuming since after the determination of possible contaminations on the rear side of the mask or the incidence surface 16, a completely new determination of the pixels 6 to be produced and of the production parameters has to be established by use of corresponding calculations. If there is correspondingly a long period of time required, a mask 1 to be corrected can be removed from the apparatus provided therefor in order that this apparatus can be used for other masks, which includes the risk that further contaminations 7 might be produced during the handling of the mask 1.

In order to reduce the period of time required for a completely new determination of the pixel production for the correction of positioning errors, a predefined compensation can be effected for regions in which no pixels are intended to be produced. Such a predefined compensation of omitted pixels in regions of contaminations can be implemented independently of the specific situation of the contamination and/or the planned pixel production.

It is furthermore also possible, however, to take account of the specific situation of the contamination and/or the pixel production in the compensation.

A possibility for compensation which simultaneously allows the compensation outlay to be kept low is afforded by the use of a corresponding heuristic method, as is explained below.

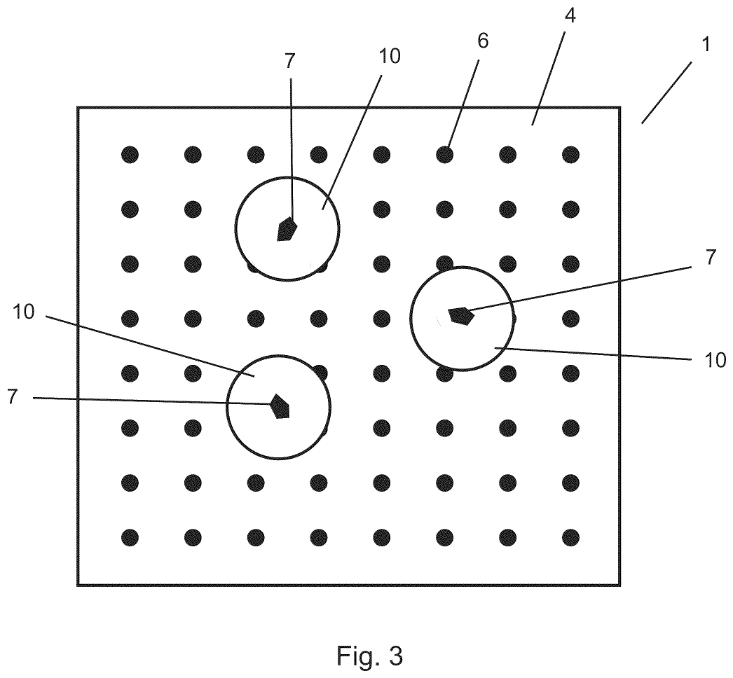

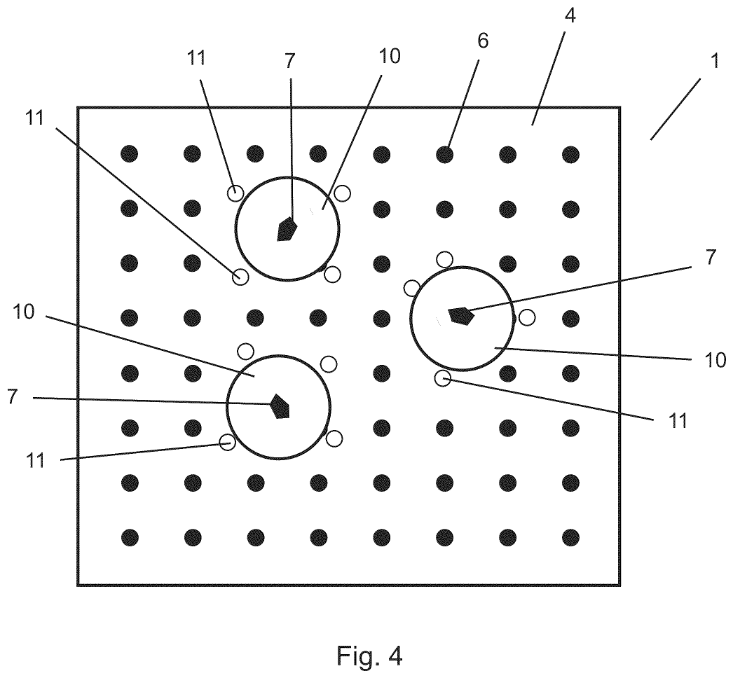

FIG. 3 shows a plan view of the rear side or incidence surface of a mask 1, on which contaminations 7 are present, which have been detected during a surface examination by use of corresponding microscopic methods or other detection methods. All microscopic methods suitable for detecting contaminations can be applied. The methods may include but are not restricted to methods using optical microscopes, fluorescence microscopes, electron microscopes both transmission electron microscopes and scanning electron microscopes and scanning probe microscopes. In addition, the partial extract from the rear-side coating 4 of the mask 1 shows for schematic illustration possible pixels 6 such as can be provided for reducing positioning errors of structures of the mask 1 in the substrate 2 of the mask 1 or have been determined on account of the placement errors of the structure elements of the mask 1. FIG. 3 furthermore shows the pixel-free regions 10 around the corresponding contaminations 7 when the contaminations 7 are projected into the plane of the pixels 6. It is easily discernible that the pixel-free regions 10 cover some of the envisaged pixels 6, with the result that these pixels 6 cannot be produced. In order, however, to maintain the correction effect of the pixels 6 as much as possible, an offset of the pixels 6 planned in the pixel-free region 10 into a region outside the pixel-free region 10 is implemented according to this embodiment of the invention. This is illustrated in FIG. 4. Here it can be seen that some offset pixels 11 are produced outside the pixel-free region 10 in order largely to maintain the correction effect of the pixels 6 on the placement errors of the structures.

The number of offset pixels may be determined by simulation calculations. FIG. 4 shows the use of 4 offset pixels for each contamination 7. It is possible to use 1, 2, 3, 5, 6, 7, 8, 9, 10 or more offset pixels for each contamination 7. Further it is possible to use different numbers of offset pixels for different contaminations 7. More offset pixels may be used for compensating larger contaminations, and fewer offset pixels may be used for compensating smaller contaminations.

In order to determine in a simple manner how and where the offset pixels 11 are intended to be produced, it is possible to define an offset radius around a contamination 7 or a pixel 6 which has to be omitted within which the pixel 6 which has to be omitted due to a contamination is intended to be reproduced or replaced as one or more offset pixels 11. Alternatively, the offset pixels 11 can be produced on a circle with the offset radius. The offset radius may be determined by simulation calculation and defines the area of possible positions of offset pixels 11 which are beneficial in terms of effective compensation of omitted pixels 6 and low impact on adjacent pixels 6.

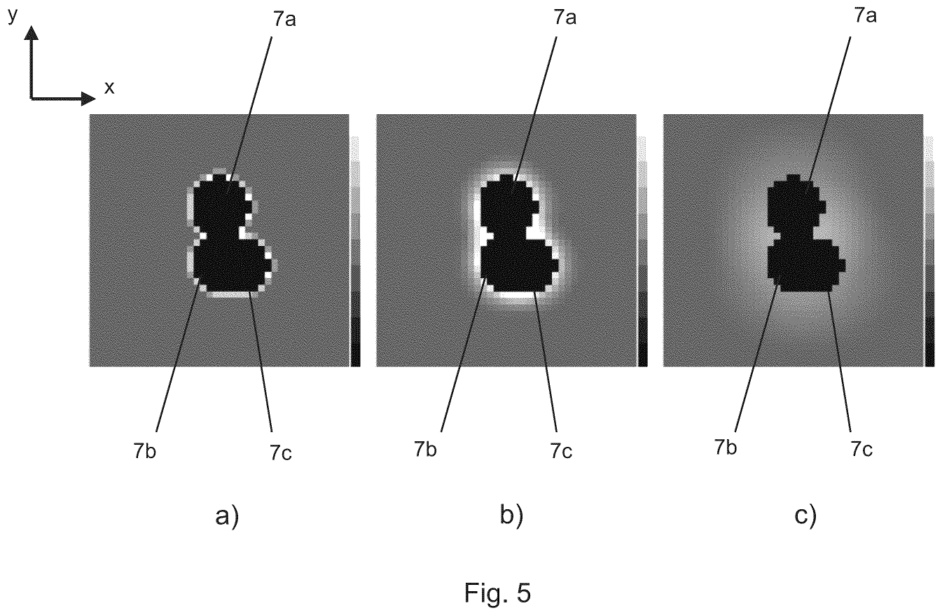

FIG. 5 shows, in the partial images a) to c), a simulation for a heuristic offset of pixels on the basis of different offset radii on account of contaminations 7a to 7c and pixel-free regions associated therewith. The partial images a) to c) each show the pixel concentration over a corresponding area, where the pixel concentration is equal to 0 in black regions, while a high pixel concentration is present in regions shown in white. The offset radius for the pixels is 100 μm in the partial image a) in FIG. 5, while the offset radius is 400 μm in the partial image b), and the offset radius is 1000 μm in the partial image c). As is easily discernible in the partial images in FIG. 5, a small offset radius gives rise to a concentration of pixels in direct proximity to the contaminations 7a, 7b and 7c which are arranged in a triangle, the contaminations 7a and 7b that are adjacent to one another in the Y-direction being spaced further apart from one another than the contaminations 7b and 7c that are adjacent to one another in the X-direction.

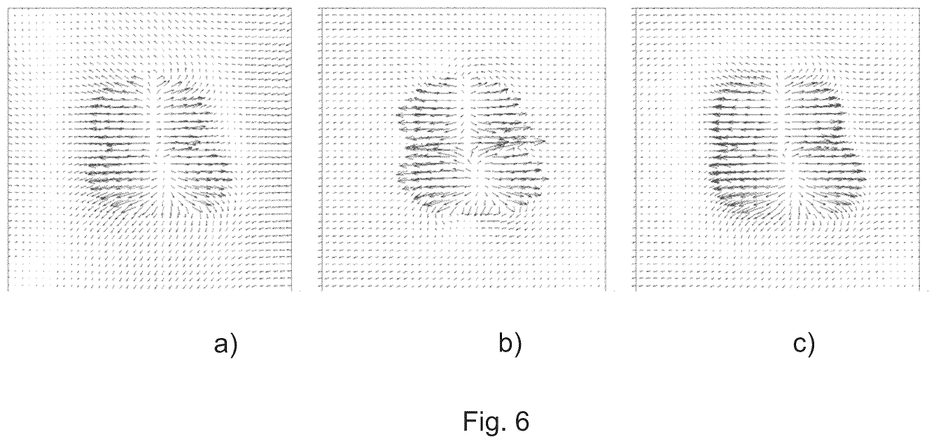

The corresponding influence of the implemented compensation by use of the heuristic offset of omitted pixels from regions with contaminations is illustrated in FIG. 6, for the examples from FIG. 5. In the corresponding partial images a) to c), the arrows shown over the area represent the corresponding placement errors of the structures that remain after applying the compensation.

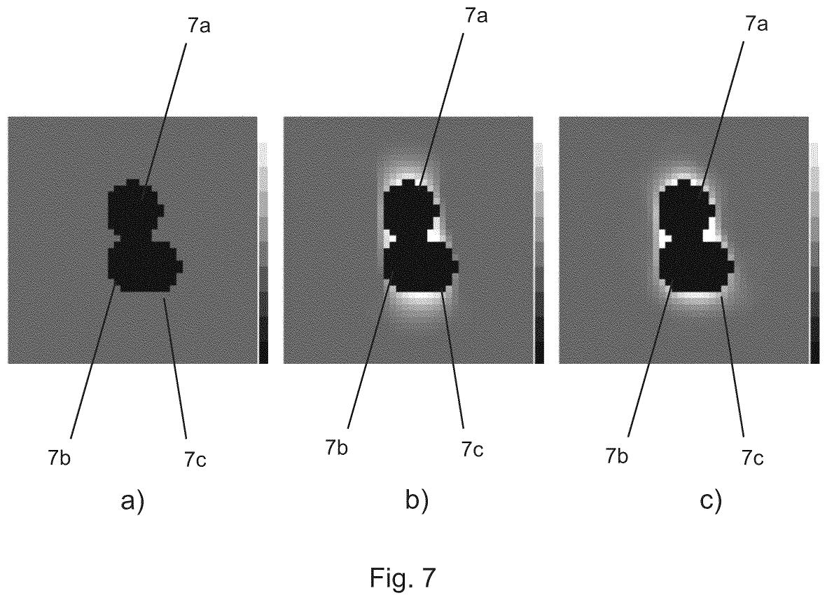

FIG. 7 shows, in the partial images a) to c), the simulated pixel distribution in the case of an area with contaminations 7a, 7b and 7c, as in the case of the situation in FIG. 5, but where the partial image a) shows the situation when no compensation at all is implemented for the pixels 6 omitted in the region of the contaminations 7a to 7c, while the partial image b) in FIG. 7 shows the situation when in the case of a compensation with an offset of the omitted pixels according to the above-described heuristic offset of pixels, this is optimized with regard to a minimization of the placement errors. The partial image c) in FIG. 7 shows the pixel distribution (black=no pixels, white means a high concentration of pixels) in the event of a complete compensation of the omitted pixels having been implemented by use of a new determination of the pixel production.

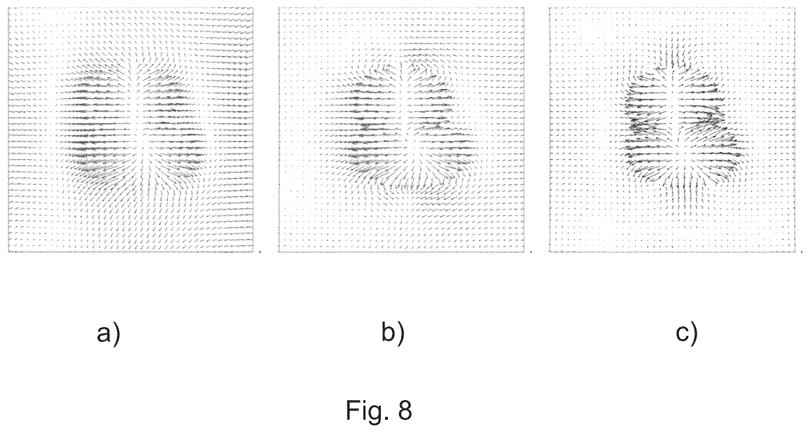

FIG. 8 shows, once again in the partial images a) to c), the influence of the various methods on the placement errors which can be observed in the region of the corresponding contaminations. Again, the arrows shown over the area represent the corresponding placement errors of the structures that remain after applying the compensation. The partial images a) to c) in FIG. 8 correspond to the situations in the partial images a) to c) in FIG. 7.

From FIG. 8 and the table below, which indicates the placement errors in the form of an interval of the 3-fold standard deviation for different compensations for dispensing with the production of pixels in the region of contaminations, it is evident that the placement errors expressed by an interval of the 3-fold standard deviation of the position of the structures in the case of omission of pixels in the region of contaminations without compensation leads to an increase in the placement error in comparison with a complete compensation by use of redetermination of the pixels to be produced taking account of the contaminations. However, it can also be seen that the heuristic offset of omitted pixels with the aid of an offset radius, just like the offset of pixels which is optimized with regard to the placement errors, leads only to a slight increase in the placement errors, particularly if a small offset radius is chosen.

TABLE
Influence on the placement error on the part of the various procedures when
omitting pixels on account of contaminations

| | | Placement error ± |
|---|---|---|
| Procedure | Radius in μm | 3σ in nm |
| No offset | | 0.156 |
| Heuristic offset | 100 | 0.139 |
| | 200 | 0.134 |
| | 300 | 0.138 |
| | 400 | 0.147 |
| | 500 | 0.156 |
| | 1000 | 0.177 |
| | 2000 | 0.186 |
| Optimized offset | | 0.131 |
| Complete | | 0.121 |
| compensation | | |

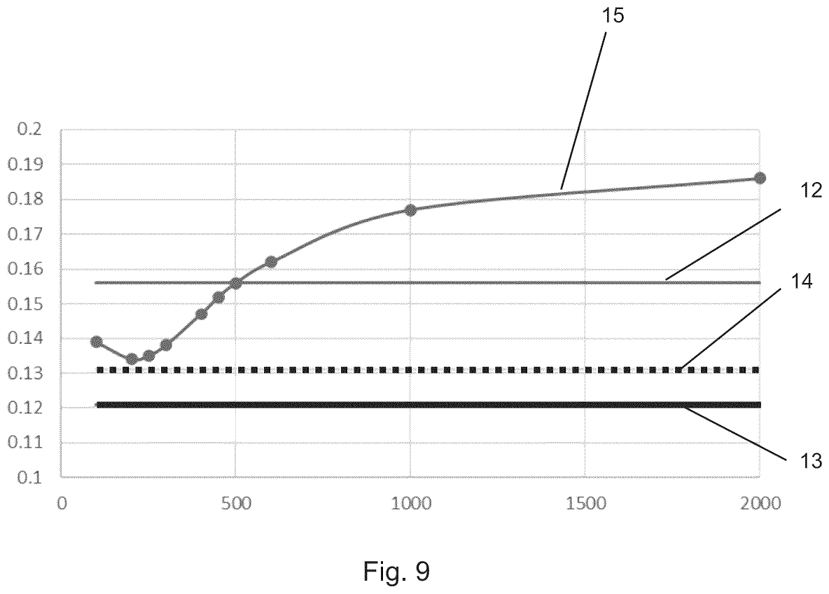

The results of the table are also illustrated in a diagram in FIG. 9, the respective placement error in the case of simple omission of the pixels without compensation 12, in the case of an optimized offset 14 of the omitted pixels and in the case of a complete compensation 13 being independent of a possible offset radius, thus giving rise to a straight line parallel to the abscissa axis. A dependence on the offset radius arises for the heuristic offset 15, where in the case of the optimum offset radius in the case of the heuristic offset, the result obtained for a possible placement error can be approximately as good as in the case of an optimized offset of the pixels.

In some implementations, the controller 28 can include analog and/or digital electronic circuitry for implementing the control functions, and input/output ports for sending and/or receiving control and/or data signals. The computer 29 can include one or more data processors configured to execute one or more programs that include a plurality of instructions according to the principles described above. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include thousands, millions, or billions of transistors.

In some implementations, the processing of data described in this document, such as examining data from the detection system 27 to identify contaminations, determining whether to introduce pixels into the regions assigned to respective contaminations, determining the offset radius, determining the number and locations of the pixels, and determining the parameters of the laser beam, can be carried out using one or more computers (e.g., 29), which can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker. In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Although the present invention has been described in detail on the basis of the exemplary embodiments, it is obvious to a person skilled in the art that the invention is not restricted to these exemplary embodiments, rather that modifications are possible such that individual features can be omitted or different types of combinations of features can be implemented, without departing from the scope of protection of the appended claims. In particular, the present disclosure includes all combinations of the individual features shown in the various exemplary embodiments, such that individual features described only in connection with one exemplary embodiment can also be used in other exemplary embodiments or in not explicitly presented combinations of individual features.

### LIST OF REFERENCE SIGNS

1 Mask
2 Substrate
3 Reflection coating
4 Rear-side coating
5 Laser beam
6 Pixel (local density change)
7, 7a, 7b, 7c Contamination (particle)
8 Region of the contamination
9 Margin around contamination
10 Pixel-free region
11 Offset pixels
12 Placement error without compensation of omitted pixels
13 Placement error with complete compensation of omitted pixels
14 Placement error with optimized offset of omitted pixels
15 Placement error with heuristic offset of omitted pixels
16 Incidence surface
20 Device for correcting placement error
21 Clamping device
22 Objective
23 Positioning device
24 Dichromatic mirror
25 Mirror
26 Pulse laser
27 Detection system
28 Controller
29 Computer

What is claimed is:

1. A method for correcting placement errors in a photolithographic mask comprising a substrate and structures formed on the substrate, the method involving at least one local density change, each of which defines a pixel, being introduced into the substrate by use of a laser beam in order to correct placement errors of the structures,
wherein in an examination step, an incidence surface of the mask, via which the laser beam radiates into the substrate, is examined for contaminations and, in regions in which a contamination of the incidence surface has been ascertained in the examination step, no laser irradiation or a laser irradiation with at least one changed laser beam parameter takes place, the laser beam parameter(s) being changed such that no damage to the incidence surface or near-surface regions occurs in the case of an interaction between laser beam and contamination.

2. The method of claim 1, wherein the laser beam parameters are selected from the group comprising the location of the focal point in the substrate, the numerical aperture of the laser beam, the wavelength of the laser beam light used, the writing speed of the laser beam with regard to the number of pixels per unit time, the focal point size of the laser beam, the beam diameter at the incidence surface, the energy of the laser beam, the beam intensity of the laser beam, the intensity profile of the laser beam, the pulse duration, the repetition rate, the pulse power and the pulse power density in the case of pulsed lasers.

3. The method of claim 1, wherein in the case of the laser irradiation in the region of contaminations on the incidence surface, at least one of the measures is implemented from the group comprising increasing the numerical aperture of the laser beam, reducing the laser beam intensity, reducing the repetition rate, reducing the writing speed with regard to the number of pixels per unit time, reducing the laser beam energy, reducing the pulse power, reducing the pulse duration and reducing the pulse power density.

4. The method of claim 1, wherein in the case of dispensing with the laser irradiation or in the case of a laser irradiation with at least one changed laser beam parameter, no laser irradiation or a laser irradiation with at least one changed laser beam parameter takes place only in a region with the contamination or in a region with the contamination with a defined spacing around the contamination, the spacing around the contamination being in particular 1 to 100 times the largest dimension of the contamination along the incidence surface.

5. The method of claim 1, wherein in order to produce the correction of the placement errors, the distribution and/or properties of the pixels and/or the laser beam parameters is/are determined, the determination of the distribution and/or the properties of the pixels and/or the laser beam parameters being effected in a way that takes account of the detected contaminations.

6. The method of claim 1, wherein in order to produce the correction of the placement errors, the distribution and/or properties of the pixels and/or the laser beam parameters is/are determined and subsequently the examination step for determining contamination of the incidence surface is carried out and, in regions in which in the examination step a contamination of the incidence surface has been ascertained and, consequently, no laser irradiation takes place and no pixels with density variation are produced, a compensation for omitted pixels is implemented.

7. The method of claim 6, wherein the compensation for pixels omitted on account of contaminations is effected by use of a fixedly predefined compensation or a compensation depending on the ascertained contaminations is effected.

8. The method of claim 7, wherein the compensation depending on the ascertained contamination is effected by the pixel(s) omitted in a region with the contamination and/or with a defined spacing around the contamination being displaced to a location which lies within a zone or on a circle with a specific radius provided around the original pixel.

9. The method of claim 7, wherein the distribution and/or properties of the pixels and/or the laser beam parameters is/are optimized with regard to a minimization of the placement errors, in particular with regard to a minimization of the interval of ±3 σ of the placement errors.

10. The method of claim 1 wherein the at least one local density change comprises a plurality of local density changes.

11. The method of claim 10 wherein in the case of the laser irradiation in the region of contaminations on the incidence surface, at least one of the measures is implemented from the group comprising increasing the numerical aperture of the laser beam, reducing the laser beam intensity, reducing the repetition rate, reducing the writing speed with regard to the number of pixels per unit time, reducing the laser beam energy, reducing the pulse power, reducing the pulse duration and reducing the pulse power density.

12. The method of claim 10 wherein in the case of dispensing with the laser irradiation or in the case of a laser irradiation with at least one changed laser beam parameter, no laser irradiation or a laser irradiation with at least one changed laser beam parameter takes place only in a region with the contamination or in a region with the contamination with a defined spacing around the contamination, the spacing around the contamination being in particular 1 to 100 times the largest dimension of the contamination along the incidence surface.

13. The method of claim 10 wherein in order to produce the correction of the placement errors, the distribution and/or properties of the pixels and/or the laser beam parameters is/are determined, the determination of the distribution and/or the properties of the pixels and/or the laser beam parameters being effected in a way that takes account of the detected contaminations.

14. The method of claim 10 wherein in order to produce the correction of the placement errors, the distribution and/or properties of the pixels and/or the laser beam parameters is/are determined, the determination of the distribution and/or the properties of the pixels and/or the laser beam parameters being effected in a way that takes account of the detected contaminations.

15. The method of claim 10 wherein in order to produce the correction of the placement errors, the distribution and/or properties of the pixels and/or the laser beam parameters is/are determined and subsequently the examination step for determining contamination of the incidence surface is carried out and, in regions in which in the examination step a contamination of the incidence surface has been ascertained and, consequently, no laser irradiation takes place and no pixels with density variation are produced, a compensation for omitted pixels is implemented.

16. The method of claim 3, comprising, in each region in which a contamination of the incidence surface has been ascertained in the examination step, applying a laser irradiation with at least one changed laser beam parameter taking place, as compared to a first region in which no contamination of the incidence surface has been ascertained in the examination step, including at least one of (i) increasing the numerical aperture of the laser beam irradiating the region of contamination on the incidence surface, or (ii) reducing at least one of the intensity, the energy, the pulse power, the pulse duration, or the pulse power density of the laser beam irradiating the region of contamination on the incidence surface, such that no damage to the incidence surface or near-surface regions occurs in case there is an interaction between the laser beam and the contamination.

17. A method comprising:
examining an incidence surface of a photolithographic mask for contaminations, wherein the photolithographic mask comprises a substrate and structures formed on the substrate, and the mask has placement errors; and
correcting at least some of the placement errors, comprising:
in each of a first set of regions of the substrate in which no contamination of the corresponding incidence surface has been found from the examination, applying a laser irradiation to the region of the substrate using a laser beam that passes through the incidence surface; and
in each of a second set of regions of the substrate in which a contamination of the corresponding incidence surface has been found from the examination, performing at least one of (i) not applying laser irradiation, or (ii) applying a laser irradiation to the region of the substrate with at least one modified laser beam parameter, as compared to the laser irradiation applied to the first set of regions, the at least one modified laser beam parameter being configured such that no damage to the incidence surface or near-surface regions occurs in case of an interaction between the laser beam and the contamination.

18. The method of claim 17 wherein the photolithographic mask comprises a reflection layer, and the incidence surface is on an opposite side of the substrate relative to the reflection layer.

19. The method of claim 17 wherein correcting at least some of the placement errors comprises: in each of the second set of regions of the substrate in which laser irradiation is not applied and no pixels with density variation are produced, performing a compensation for omitted pixels, wherein the compensation for pixels omitted on account of contaminations comprises applying a compensation that depends on the ascertained contaminations,
wherein applying the compensation comprises displacing the pixel or pixels omitted in at least one of (i) the region with the contamination, or (ii) a region with a defined spacing around the contamination, to a location which lies within a zone or on a circle with a specific radius provided around the pixel or pixels omitted.

20. The method of claim 17 wherein correcting at least some of the placement errors comprises: in each of the second set of regions of the substrate in which a contamination of the corresponding incidence surface has been found from the examination, applying the laser irradiation to the region of the substrate with at least one modified laser beam parameter, as compared to the laser irradiation applied to the first set of regions, including at least one of (i) increasing a numerical aperture of the laser beam irradiating the region of contamination on the incidence surface, (ii) reducing at least one of an intensity, an energy, a pulse power, a pulse duration, or a pulse power density of the laser beam irradiating the region of contamination on the incidence surface, (iii) reducing a repetition rate of the laser beam irradiating the region of contamination on the incidence surface, or (iv) reducing a writing speed with regard to the number of pixels per unit time, such that no damage to the incidence surface or near-surface regions occurs in case there is an interaction between the laser beam and the contamination.
